(19) United States
(12) Patent Application Publication
(10) Pub. No.: US 2014/0270256 A1
(43) Pub. Date: Sep. 18, 2014

(54) Modifying Control Resolution

(71) Applicants: Yoshinari Yoshikawa, Los Altos, CA (US); Keisuke Shingu, San Francisco, CA (US)

(72) Inventors: Yoshinari Yoshikawa, Los Altos, CA (US); Keisuke Shingu, San Francisco, CA (US)

(73) Assignee: MISELU, INC., San Francisco, CA (US)

(21) Appl. No.: 13/841,249

(22) Filed: Mar. 15, 2013

(51) Int. Cl. H03G 3/02

(52) U.S. Cl. CPC H03G 3/02
USPC 381/109

(57) ABSTRACT

Embodiments generally relate to controlling music variables. In one embodiment, a method includes determining an initial control position of at least one control member of a hardware control device. The method also includes determining an initial dial position of at least one dial. The method also includes modifying a value of at least one sound variable based on the initial control position, the initial dial position, and movement of the at least one control member.

### BACKGROUND

The creation of music is a popular activity enjoyed by many people. Some music applications enable a listener to control music variables such as volume, balance, reverb, etc. For example, a music application may provide a volume slider on a touchscreen that enables a user to increase or decrease volume by placing a finger on the slider to move the slider.

### SUMMARY

Embodiments generally relate to controlling music variables. In one embodiment, a method includes determining an initial control position of at least one control member of a hardware control device. The method also includes determining an initial dial position of at least one dial. The method also includes modifying a value of at least one sound variable based on the initial control position, the initial dial position, and movement of the at least one control member.

In another embodiment, a computer-readable storage medium carries one or more sequences of instructions thereon. When executed by a processor, the instructions cause the processor to perform operations including determining an initial control position of at least one control member of a hardware control device. The instructions further cause the processor to perform operations including determining an initial dial position of at least one dial. The instructions further cause the processor to perform operations including modifying a value of at least one sound variable based on the initial control position, the initial dial position, and movement of the at least one control member.

In another embodiment, a system includes one or more processors, and includes logic encoded in one or more tangible media for execution by the one or more processors. When executed, the logic is operable to perform operations including determining an initial control position of at least one control member of a hardware control device. The logic is operable to perform operations including determining an initial dial position of at least one dial. The logic is operable to perform operations including modifying a value of at least one sound variable based on the initial control position, the initial dial position, and movement of the at least one control member.

### BRIEF DESCRIPTION OF THE DRAWINGS

FIG. 1 is a block diagram of an example system, which may be used to implement the embodiments described herein.

FIG. 2 shows an example perspective view of a knob, which may be used to implement a control member associated with a hardware control device, according to some embodiments.

FIG. 3 shows an example top view of the knob of FIG. 2, according to some embodiments.

FIG. 4 shows an example top view of a slider, which may be used to implement a control member associated with a hardware control device, according to some embodiments.

FIG. 5 shows an example dial, according to some embodiments.

FIG. 6 shows another example dial, according to some embodiments.

FIG. 7 shows another example dial, according to some embodiments.

FIG. 8 illustrates an example simplified flow diagram for controlling music variables, according to some embodiments.

FIG. 9 illustrates an example simplified flow diagram for controlling music variables, according to some embodiments.

FIG. 10 illustrates an example top view of a control member that is set at 0% of its control range of motion, according to some embodiments.

FIG. 11A illustrates an example virtual dial that is set at 0% of its dial range of motion, according to some embodiments.

FIG. 11B illustrates an example virtual dial that is set at 25% of its dial range of motion, according to some embodiments.

FIG. 11C illustrates an example virtual dial that is set at 50% of its dial range of motion, according to some embodiments.

FIG. 11D illustrates an example virtual dial that is set at 75% of its dial range of motion, according to some embodiments.

FIG. 11E illustrates an example virtual dial that is set at 100% of its dial range of motion, according to some embodiments.

FIG. 12 illustrates an example top view of a control member that is set at 50% of its control range of motion, according to some embodiments.

FIG. 13A illustrates an example virtual dial that is set at 0% of its dial range of motion, according to some embodiments.

FIG. 13B illustrates an example virtual dial that is set at 25% of its dial range of motion, according to some embodiments.

FIG. 13C illustrates an example virtual dial that is set at 50% of its dial range of motion, according to some embodiments.

FIG. 13D illustrates an example virtual dial that is set at 75% of its dial range of motion, according to some embodiments.

FIG. 13E illustrates an example virtual dial that is set at 100% of its dial range of motion, according to some embodiments.

FIG. 14 illustrates an example top view of a control member that is set at 100% of its control range of motion, according to some embodiments.

FIG. 15A illustrates an example virtual dial that is set at 0% of its dial range of motion, according to some embodiments.

FIG. 15B illustrates an example virtual dial that is set at 25% of its dial range of motion, according to some embodiments.

FIG. 15C illustrates an example virtual dial that is set at 50% of its dial range of motion, according to some embodiments.

FIG. 15D illustrates an example virtual dial that is set at 75% of its dial range of motion, according to some embodiments.

FIG. 15E illustrates an example virtual dial that is set at 100% of its dial range of motion, according to some embodiments.

### DETAILED DESCRIPTION

Embodiments described herein enable a user to control music variables. As described in more detail below, a system enables a user to control music variables, also referred to as sound variables, using a combination of hardware elements (e.g., a physical knob) and software elements (e.g., a dial). Such sound variables may include variables such as volume, balance, reverb, pitch, tempo, effects, etc. Embodiments provide intuitive and precise control of sound variables using hardware elements. Embodiments also provide software elements, which increase the flexibility and range of use of the hardware interface, and also enable efficient modification of variable inputs from the hardware elements. Such a combination of hardware elements and software elements provides optimal control of music.

In some embodiments, the system includes a processor and a hardware control device that is operable to send one or more control signals to the processor, where the one or more control signals control one or more sound variables. The user may control the hardware control device in part via one or more physical controls referred to hereinafter as control members. Types of control members may include knobs, sliders, switches, buttons, etc. The system also includes a visual display that displays one or more virtual (software) graphical representations of dials, hereafter referred to as dials, where the one or more dials are associated with the one or more sound variables. For example, a given virtual dial may indicate volume level. The processor of the system causes the one or more dials to change based on the one or more control signals. For example, if a given control signal associated with volume causes the volume to increase, a corresponding dial showing volume level changes to indicate the increase in volume.

As described in more detail below, the system determines an initial control position of at least one control member of a hardware control device. As indicated above, the control member may be a physical knob, slider, switch, button, etc. The system also determines an initial dial position of one or more dials. In various implementations, the system modifies the values of one or more sound variables based on the initial control position, the initial dial position, and movement of the at least one control member. In various implementations, the movement of a single control member may simultaneously change multiple associated dials and sound variables.

Embodiments described herein provide various benefits. For example, embodiments enable a user to intuitively and precisely control one or more music variables using a physical controller such as a knob or slider. Embodiments also enable a user to conveniently see how such music variables change using one or more software indicators such as virtual dials. Embodiments also enable a user to increase or decrease the resolution of one or more dials based on initial settings of a given physical controller and the one or more dials.

FIG. 1 is a block diagram of an example system 100, which may be used to implement the embodiments described herein. In various embodiments, system 100 may be implemented in a musical instrument (e.g., keyboard, etc.) or in any suitable computer system (e.g., sound controller, etc.). In some implementations, system 100 may include a processor 102, an operating system 104, a memory 106, a music application 108, a network connection 110, a microphone 112, a touchscreen 114, and a speaker 116. For ease of illustration, the blocks shown in FIG. 1 may each represent multiple units. In other embodiments, system 100 may not have all of the components shown and/or may have other elements including other types of elements instead of, or in addition to, those shown herein.

Music application 108 may be stored on memory 106 or on any other suitable storage location or computer-readable medium. Music application 108 provides instructions that enable processor 102 to perform the functions described herein. In various embodiments, music application 108 may run on any electronic device including smart phones, tablets, computers, musical instruments, etc.

In various embodiments, touchscreen 114 may be separate from system 100 or integrated with system 100. For example, as shown in FIG. 1, touchscreen 114 is integrated with system 100. In some embodiments, touchscreen 114 may be separate from system 100, where touchscreen 114 is integrated with a separate device such as a tablet, computer, smartphone, etc.

In various embodiments, touchscreen 114 may include any suitable interactive display surface or electronic visual display that can detect the presence and location of a touch within the display area. Touchscreen 114 may support touching the display with a finger or hand, or any suitable passive object, such as a stylus. Any suitable display technology (e.g., liquid crystal display (LCD), light emitting diode (LED), etc.) can be employed in touchscreen 114. In various embodiments described herein, the term “touchscreen” may be used interchangeably with the term “display.” In addition, touchscreen 114 in particular embodiments may utilize any type of touch detecting technology (e.g., resistive, surface acoustic wave (SAW) technology that uses ultrasonic waves that pass over the touchscreen panel, a capacitive touchscreen with an insulator, such as glass, coated with a transparent conductor, such as indium tin oxide (ITO), surface capacitance, mutual capacitance, self-capacitance, projected capacitive touch (PCT) technology, infrared touchscreen technology, optical imaging, dispersive signal technology, acoustic pulse recognition, etc.).

In various embodiments, processor 102 may be any suitable processor or controller (e.g., a central processing unit (CPU), a general-purpose microprocessor, a micro-controller, a microprocessor, etc.). Further, operating system 104 may be any suitable operating system (OS), or mobile OS/platform, and may be utilized to manage operation of processor 102, as well as execution of various application software. Examples of operating systems include Android from Google, iPhone OS (iOS), Berkeley software distribution (BSD), Linux, Mac OS X, Microsoft Windows, and UNIX.

While processor 102 is described as performing the steps as described in the embodiments herein, any suitable component or combination of components of system 100 or any suitable processor or processors associated with system 100 or any suitable system may perform the steps described.

In various embodiments, memory 106 may be used for instruction and/or data memory, as well as to store music and/or video files created on or downloaded to system 100. Memory 106 may be implemented in one or more of any number of suitable types of memory (e.g., static random access memory (SRAM), dynamic RAM (DRAM), electrically erasable programmable read-only memory (EEPROM), etc.). Memory 106 may also include or be combined with removable memory, such as memory sticks (e.g., using flash memory), storage discs (e.g., compact discs, digital video discs (DVDs), Blu-ray discs, etc.), and the like. Interfaces to memory 106 for such removable memory may include a universal serial bus (USB), and may be implemented through a separate connection and/or via network connection 110.

In various embodiments, network connection 110 may be used to connect other devices and/or instruments to system 100. For example, network connection 110 can be used for wireless connectivity (e.g., Wi-Fi, Bluetooth, etc.) to the Internet (e.g., navigable via touchscreen 114), or to another device. Network connection 110 may represent various types of connection ports to accommodate corresponding devices or types of connections. For example, additional speakers (e.g., Jawbone wireless speakers, or directly connected speakers) can be added via network connection 110. Also, headphones via the headphone jack can also be added directly, or via wireless interface. Network connection 110 can also include a USB interface to connect with any USB-based device.

In various embodiments, network connection 110 may also allow for connection to the Internet to enable processor 102 to send and receive music over the Internet. As described in more detail below, in some embodiments, processor 102 may generate various instrument sounds coupled together to provide music over a common stream via network connection 110.

In various embodiments, speaker 116 may be used to play sounds and melodies generated by processor 102. Speaker 116 may also be supplemented with additional external speakers connected via network connection 110, or multiplexed with such external speakers or headphones.

In various embodiments, system 100 also includes hardware control device 118. Hardware control device 118 is operable to send one or more control signals to processor 102, where the one or more control signals control one or more sound variables. Such sound variables may include, for example, volume, balance, etc. In various embodiments, hardware control device 118 includes one or more physical, movable control portions or control members such as a knob, a slider, etc. Such control members are movable. For example, a control member that is a knob that can rotate. In another example, a control member that is a slider that can slide. In various embodiments, hardware control device 118 includes an electric circuit that measures physical movement (e.g., rotation of a knob, displacement of a slider or button or switch, etc.) and converts such movement into an electronic control signal.

In some embodiments, hardware control device 118 may be implemented as a peripheral device that is physically separated from system 100. For example, as shown, hardware control device 118 is integrated with system 100. In some embodiments, hardware control device 118 may be a stand-alone peripheral device with a knob, slider, etc. that operatively connects to system 100, where the connection may be a wireless or wired connection. In some embodiments, hardware control device 118 may be integrated with any other suitable device, where the other device may be a musical instrument, or music system that includes an integrated touchscreen, etc. Hardware control device 118 may or may not be integrated with the same system into which touchscreen 114 is integrated. Also, hardware control device 118 may be operatively connected to touchscreen 114 by a wireless or wired connection.

In some embodiments, control members may have multiple states (e.g., closed/collapsed state, open/deployed state, etc.). For example, a given control member may collapse to allow for a low profile when not in use, and may open (e.g., pop up, telescope up, fold up, etc. to allow for normal operation when in use).

Note that the term “hardware” in “hardware control device” indicates a control device that is a physical hardware mechanism. Also, as described in more detail below, a control member associated with hardware control device 118 may be implemented in different ways (e.g., as a knob, as a slider, etc.). Example embodiments directed to hardware control device 118 and different examples of control members are described in more detail below in connection with FIGS. 2, 3, and 4.

FIG. 2 shows an example perspective view of physical knob 200, which may be used to implement a control member associated with hardware control device 118, according to some embodiments. As shown, knob 200 is movable in that it rotates clockwise and counter clockwise in order to modulate a control signal that hardware control device 118 sends to processor 102. In various embodiments, the control signal controls one or more sound parameters based on the relative position of knob 200.

FIG. 3 shows an example top view of knob 200 of FIG. 2, according to some embodiments. As shown, in some embodiments, knob 200 has a position indicator 202 showing the positioning of knob 200 relative to position indicators 204, 206, 208, etc., where each position indicator 204, 206, 208, etc., may be associated with a different value of a sound variable. For example, in a scenario where knob 200 is controlling volume, position indicator 204 may be associated with 0 dB, position indicator 206 may be associated with 20 dB, position indicator 204 may be associated with 40 dB, etc. Accordingly, as a user rotates knob 200 clockwise, hardware control device 118 sends an appropriate control signal to processor 102 to increase the volume. These are merely example values and the particular values and measurement units assigned to the particular sound parameter will depend on the particular implementation.

As indicated above, a knob is one type of control member. Hardware control device 118 may include other types of control members such as sliders, switches, buttons, etc., and any combination thereof, depending on the particular implementation. The following example embodiments are directed to a control member that is a slider.

FIG. 4 shows an example top view of a physical slider 400, which may be used to implement a control member associated with hardware control device 118, according to some embodiments. As shown, in some embodiments, slider 400 has a position indicator 402 showing the positioning of slider 400 relative to position indicators 404, 406, 408, etc., where each position indicator 404, 406, 408, etc., may be associated with a different value of a sound variable. For example, similar to the example knob embodiments described above, slider 400 may control volume, where position indicator 404 may be associated with 0 dB, position indicator 406 may be associated with 20 dB, position indicator 404 may be associated with 40 dB, etc. Accordingly, as a user slides slider 400 from the bottom-most position corresponding to position indicator 404 toward the top-most position indicator, hardware control device 118 sends an appropriate control signal to processor 102 to increase the volume. Again, these are merely example values and the particular values and measurement units assigned to the particular sound parameter will depend on the particular implementation.

While various embodiments are described herein in the context of knobs and sliders, other types of control members are possible. For examples, hardware control device 118 may also have control members that are switches, buttons, etc., and/or any combination thereof.

In various embodiments, hardware control device 118 may include control members having various tactile features. For example, a given knob may be ribbed, knobbed, rough, etc., in order to provide the user with an intuitive tactile sense of the relative positioning of the particular control member (e.g., how much a given knob is rotated, how much a given slider is moved, etc.). In some embodiments, hardware control device 118 may include various haptic mechanisms to indicate a particular position. For example, referring again briefly to FIG. 3, knob 200 may click or snap into various positions (e.g., positions corresponding to position indicators 204, 206, 208, etc.). Such tactile features enhance a physical control member's inherent ability to enable a user to control sound parameters without having to look at the control member.

In various embodiments, touchscreen 114 displays one or more virtual dials, where such dials are associated with the one or more sound variables (e.g., volume, balance, reverb, etc.). In various embodiments, a dial is a used to display settings, measurements, and/or output representations of sound variables. Dials may be of any shape (e.g., circular, rectangular/linear, etc.), and different dials may have different combinations of shapes, depending on the particular implementations. In various embodiments, a dial is a software dial that indicates the state or states of a sound variable. Also, as described in more detail below, a dial may also function as a control in that the dial may be selected (e.g., by touch, by gesture, etc.) in order to associate the dial with a given physical control member. While some embodiments are described herein in the context of sound variables, such embodiments and others may also apply to any software variables. Examples other software variables may include lighting, stage effects such as laser lights or fog effects, etc.

In various embodiments, dials may have different markings (e.g., notches, numbers, letters, etc.), different numbers of graduations or calibrations, and different dials may have different markings, depending on the particular implementations (e.g., number of different states, resolution of state levels, units for each sound variable, etc.). As described in more detail below, in various embodiments, processor 102 causes the one or more dials to change based on the one or more control signals, which are provided by one or more control members of hardware control device 118.

In various embodiments, one or more of the dials are graphical representations of at least one control member. For example, referring to both FIGS. 3 and 5, virtual dial 500 of FIG. 5 may be a software or graphical representation of physical knob 200 of FIG. 3.

FIG. 5 shows an example dial 500, according to some embodiments. As shown, dial 500 may be a graphical (virtual) representation of physical knob 200 of FIG. 3. Dial 500 is an example of a circular dial. In this particular example, dial 500 indicates volume level using a position indicator 502.

FIG. 6 shows another example dial 600, according to some embodiments. Dial 600 may also be a graphical (virtual) representation of physical knob 200 of FIG. 3. Dial 600 is another example of a circular dial. In this particular example, dial 600 indicates balance between left and right speakers using a position indicator 602.

FIG. 7 shows another example dial 700, according to some embodiments. Dial 700 may be a graphical representation of physical slider 400 of FIG. 4. Dial 700 is an example of a rectangular or linear dial. As shown, dial 700 is oriented in a horizontal position. In some embodiments, dial 700 may be oriented in a vertical position in order to resemble physical slider 400. In various embodiments, an x-y displacement of slider 400 associated with dial 700 may cause a change in the sound variable associated with dial 700, and cause a change to dial 700 (e.g., cause a change to position indicator 702). Note that in various embodiments, any given dial may be a graphical representation of any given control member. In various embodiments, the shape (e.g., circular, rectangular, etc.) and orientation (e.g., vertical, horizontal, etc.) of a given dial may be independent of the control member to which the dial is associated. For example, dial 700 may also be a graphical representation of physical knob 200 of FIG. 3. Using a physical knob has a benefit of saving space on a console (as compared to sliders, for example). As such, a rotational change of a physical knob (e.g., knob 200) associated with dial 700 may cause a change in the sound variable associated with dial 700, and cause a change to dial 700.

Various embodiments involving the operation of the control members and dials are described in more detail below in connection with FIG. 8.

FIG. 8 illustrates an example simplified flow diagram for controlling music variables, according to some embodiments. In various embodiments, a method is initiated in block 202 where processor 102 of system 100 causes one or more dials to be displayed (e.g., in touchscreen 114), where the one or more dials are associated with the one or more sound variables.

In block 204, processor 102 receives one or more control signals from hardware control device 118, where the one or more control signals control one or more sound variables. In various embodiments, a given control member of hardware control device 118 controls one or more sound variables via control signals based on user selections that associate the given control member with one or more dials associated with such sound variables. In other words, a given control member (e.g., knob) is associated with one or more dials (e.g., volume dial) by user selection, and the given control member is hence associated with the sound parameters (e.g., volume) associated with their respective dials (e.g., volume dial). Thus, touchscreen 114 provides visual feedback of the user's tactile manipulation of the physical control member(s).

In block 206, processor 102 changes one or more of the dials based on the one or more control signals. As indicated above, hardware control device 118 has one or more control members. For example, hardware control device 118 may have a knob for controlling a sound variable such as volume. For ease of illustration, some embodiments described herein may describe a single control member. However, these and other embodiments also apply to multiple control members and multiple types of control members (e.g., knobs, sliders, switches, buttons, etc., and any combination thereof).

In various embodiments, the user may select one or more dials to be associated with a given control member. In other words, multiple dials (and corresponding sound parameters) may be associated with each control member. For example, two or more channels having two or more volume levels may be associated with (and thus controlled by) a single knob.

In various embodiments, when the user selects one or more dials, processor 102 receives the selection and then associates the selected dials with the control member that is associated with the hardware control device. As a result, the control member controls the sound parameters associated with those dials. Also, by association, the selected dials become graphical representations of the control member. When the user moves the control member (e.g., rotates a knob) to change a sound parameter (e.g., increase volume), the sound parameter changes (e.g., volume is increased) and the corresponding dial changes (e.g., visually indicates that the volume is increased). If multiple dials (e.g., multiple channels) are associated with the control member, the sound parameters associated with all such dials, and the dials, change together. Various embodiments directed to selecting particular dials to be associated with a control member are described in more detail below.

In various embodiments, the changing of dials involves processor 102 causing one or more dials to change based on a degree of movement of a control member. A visual observation of a given dial enables the user to determine the state of the sound variable in proportion to the range of values in the sound variable set. For example, if the sound variable is volume, a dial marker may denote a position that is half way through the rotation of the dial. Based on the control signal from the control member, the volume variable is set at 50% of its maximum value. For example, if the user rotates a knob 180 degrees, any corresponding/associated dial changes to show a rotation of 180 degrees. In other words, dials associated with a knob change based on the degree of rotation of the knob. Similarly, dials associated with a slider change based on the amount of movement of the slider (e.g., half way, etc.). In another example, if the sound variable is pitch, a dial marker may be rendered in multiple colors such that if one quarter of the dial is in the color denoting the variable state, then the pitch variable is set to 25% of its maximum value.

In various embodiments, the portions of a given dial that change in response to movement of a corresponding control member may vary depending on the particular implementation. For example, in some embodiments, the dial may have a fixed scale (e.g., 1-100) with a moving pointer. In some embodiments, the dial may have a fixed pointer with a moving scale (e.g., 1-100). In some embodiments, the dial may have a digital reading (e.g., 50 dB, 70.5 dB, etc.) that changes.

In some embodiments, a given knob may have the capability of rotating infinitely clockwise or counter clockwise. This ability to rotate through multiple cycles enables an associated dial to have numerous states. For example, such a knob could be used to control volume; and a corresponding dial that displays digital numbers could be used to display a precise volume level (e.g., 0 dB-110 dB). So, for example, volume may be turned up manually with a physical knob, and then fine-tuned with the touchscreen display of the volume dial.

One of the many benefits of using a physical knob or slider, etc., of hardware control device 118 is that a physical control member provides more precision/higher resolution than a software-generated controller (e.g., touchscreen knob, slider, etc.). One reason is that a user can precisely control the amount/degree of movement of a given control member. This is more optimal than manipulating a software-generated controller with a finger, because a software-generated controller has inherent resolution limitations due to touchscreen technology.

In some embodiments, there may be one control member (e.g., a single knob). Any selection of one or more dials results in the selected dials being associated with the single control member by default. Where hardware control device 118 has multiple control members (e.g., multiple knobs, multiple sliders, etc.), processor 102 may associate selected dials to a particular control member in a variety of ways. For example, in one embodiment, processor 102 may cause icons representing each control member to be displayed on touchscreen 114. Processor 102 may enable the user to select a particular control member and select one or more dials to associate as a group with that control member. For instance, a volume dial and a beats per minute (BPM) dial may be associated simultaneously with a single control member to simultaneously slow down and fade out a music track before beginning a second track.

In some embodiments, as the control member and dials are selected, processor 102 may provide a visual indicator that visually indicates which control member and dials are activated/initialized. This may be achieved in a variety of ways (e.g., brightness, color, size, shape, border, border color, etc.).

The following embodiments are involve example ways processor 102 enables a user to select dials (and corresponding sound variables) to be associated with a given control member. In some embodiments, processor 102 enables a user to utilize or manipulation touchscreen 114 in order to modify the sound variables impacted by hardware control device 118. Specifically, as indicated above, processor 102 enables the user to select dials, each dial corresponding to a particular sound variable.

In some embodiments, processor 102 enables the user to select using a touch and hold process. For example, the user may select a given dial by touching and holding (e.g., continual touch) the dial on touchscreen 114, where the dial is associated with the control member while the dial is touched and thus when the control member is manipulated (e.g., when a knob is rotated).

In some embodiments, processor 102 enables the user to select using a touch activation process. For example, the user may select a given dial with a single touch of the dial on touchscreen 114. Once touched, the dial becomes active and associated with the control member, even after the user stops touching the dial. In other words, a selected dial may be persistently active once selected, until deselected.

In various embodiments, processor 102 may disassociate a given dial from a control member in a variety of ways. For example, in some embodiments, processor 102 may disassociate a given dial from a control member when a different dial is touched. As indicated above, multiple dials may be associated with one control member. This may be achieved by, for example, a combination of commands (e.g., a command to select multiple dials combined with separate commands such as touches to select individual dials). In some embodiments, processor 102 may disassociate one or more dials from a knob based on receiving a predetermined user command (e.g., a deselect command). For example, this may be achieved by, for example, a combination of commands (e.g., a command to deselect multiple dials combined with separate commands such as touches to deselect individual dials).

In some embodiments, processor 102 enables the user to select using a special touch active process, where the user may select a dial on touchscreen 114 using a combination of fingers touches. For example, in one embodiment, the user may double touch a dial, touching more than one digit in association with the dial, using a specific finger or set of fingers to touch the dial, using a stylus to touch the dial, touching the dial as part of a gesture, swiping through the dial, pinching on the dial, pinching out from the dial, etc., or any combination thereof.

In some embodiments, processor 102 may use any suitable fingerprint recognition algorithm that detects touches from a particular finger. For example, in some embodiments, the touch of each finger may have a significant meaning (e.g., select, deselected, multiple select, multiple deselect, etc.).

In some embodiments, processor 102 may use any suitable 3-dimensional gesture detection algorithm and system to recognize gestures without the user needing to physically touch touchscreen 114. For example, the user may make a predetermined gesture in the air, and processor 102 may recognize commands from the gesture (e.g., select, deselected, multiple select, multiple deselect, etc.). In some embodiments, processor 102 may use voice recognition to select dials (e.g., “select,” “deselect,” etc.).

In some embodiments, processor 102 may enable the user to define parameter changes using scripting. For example, the user may rotate a knob to increase volume for one or more channels. Processor 102 may increase the volume for the one or more channels immediately concurrently with the rotation of the knob, and then automatically increase the volume for one or more of the channels after a predetermined/user-programmed number of seconds. The actual scripting is user-defined and will depend on the specific implementation.

In some embodiments, the user may change selections (e.g., select, deselect, reselect, etc.) on the fly as the user uses a control member to control sound parameters. For example, the user may jump from sound variable to sound variable (e.g., volume, pitch, reverb, etc., and any combinations thereof) without removing the fingers from the knob/slider/etc. Looking at the dials on touchscreen 114, the user can see the current state of each sound parameter and how the user's manipulation of the control member affects such states. This is particularly useful and optimal for a user working with many different sound variables. For example, a set of percussion sounds may involve different channels, each associated with a different percussion sound [e.g., bass drum, snare drum, tom drum(s), cymbal(s), etc.]. The user may select dials corresponding to any combination of sounds in real-time as music is being played, and then control each sound variable with a single control member (e.g., knob).

FIG. 9 illustrates an example simplified flow diagram for controlling music variables, according to some embodiments. In various embodiments, a method is initiated in block 902 where processor 102 of system 100 determines an initial control position of at least one control member of a hardware control device. As indicated above, by a user moving a control member (e.g., rotating a physical knob), the hardware control device sends one or more control signals to processor 102, where the one or more control signals control one or more sound variables. Such sound variables may include variables such as volume, balance, pitch, tempo, reverb, distortion, various other effects, etc.

In various implementations, each control member has a range of motion, also referred to as a control range of motion. A control range of motion has a minimum control position and a maximum control position. As described in more detail below, in various implementations, the initial control position (in combination with initial dial positions of one or more virtual dials) determines the base value associated with each of one or more respective sound variables, and also determines how movement of the control member within its control range of motion modifies the value of each of the one or more respective sound variables.

In block 904, processor 102 determines an initial dial position of one or more dials. As indicated above, a visual display displays one or more virtual dials, where the dials are associated with sound variables.

In various implementations, each dial has a range of motion, referred to as a dial range of motion. A dial range of motion has a minimum dial position and a maximum dial position. Each dial has a position marker that moves within the dial range of motion to indicate to a user a parameter value for a given sound variable (e.g., indicate volume level).

In block 906, processor 102 modifies the value of at least one sound variable based on the initial control position, the initial dial position, and the movement of the control member.

For example, if movement of the control member (e.g., degree of rotation of a physical knob, movement of a slider, etc.) causes a particular sound variable to change (e.g., increase or decrease the volume of a particular sound, etc.), the dial associated with the control member and associated with that volume variable shows the volume level changes, indicating the increase or decrease in volume.

As described in more detail below in connection with FIGS. 10 to 15E, the amount of movement of the sound variable is based not only on the movement of a control member but also on the initial control position of the control member and the initial dial position.

Scenarios with Knob Set at 0%

FIGS. 10, 11A, 11B, 11C, 11D, and 11E illustrate scenarios where a control member (e.g., a knob) is initially set/initialized at 0% of its control range of motion, and where an associated dial is initially set/initialized at either 0%, 25%, 50%, 75%, or 100%, respectively, of its dial range of motion. These scenarios illustrate how the resolution at which a given dial (or each of multiple dials) displays changes in values of sound variables is based on the initial control position and the initial dial position.

As described in various implementations described herein, a given range of motion (e.g., dial range of motion or control range of motion), generally, refers to a rotation of up to substantially 360°. For example, if a given knob is at 0%, its position marker is at a position that is substantially at 0% or 0° of the control range of motion. In another example, if the knob is at 50%, its position marker is at a position that is substantially at 50% or 180° of the control range of motion. In yet another example, if the knob is at 100%, its position marker is at a position that is substantially at 100% or 360° of the control range of motion.

FIG. 10 illustrates an example top view of a control member 1000 that is set at 0% of its control range of motion, according to some embodiments. As shown, control member 1000 is rotated to 0% (e.g., 0°) of its control range of motion when set. In this particular example implementation, control member 1000 is a physical knob. For ease of illustration, control member 1000 is referred to as knob 1000. In various implementations, control member 1000 may be any suitable type of control member (e.g., a physical slider, etc.). As such, the implementations described herein also apply to other types of control members such as sliders.

As shown, knob 1000 has a position indicator 1002 showing the positioning of knob 1000 relative to one or more static position indicators (e.g., static position indicator 1004). As knob 1000 is rotated, position indicator 1002 moves relative to static position indicator 1004. For ease of illustration, only one static position indicator is shown. In various implementations, the specific number of static position indicators may vary, depending on the specific implementation.

In various implementations, knob 1000 has a range of motion, also referred to as a control range of motion, as indicated above. As shown, the control range of motion has a minimum control position (labeled “Min”) and a maximum control position (labeled “Max”). In various implementations, knob 1000 may be rotated clockwise toward the maximum control position, and may be rotated counter clockwise toward the minimum control position.

In various implementations described herein, knob 1000 may be set or initialized and associated with one or more virtual dials, such as dial 1100, described below in connection with FIGS. 11A through 11E.

In some implementations, knob 1000 may be set by receiving a set indication from a user. Such a set indication may be, for example, the user depressing a set button. Such a set button may be the actual knob (e.g., the knob being depressible), or may be any suitable button such as a virtual button on a touchscreen.

In some implementations, when knob 1000 is set, processor 102 determines an initial position, also referred to an initial control position, as indicated above. This initial control position may be determined by the position indicator 1002 position within the control range of motion (e.g., at 0% of the control range of motion, at 25% of the control range of motion, etc.).

In this particular example implementation, the initial control position is set at 0%. Example implementations of how knob 1000 operates when its initial control position is set at 0% are described in more detail below in connection with FIGS. 11A through 11E.

Dial Set at 0%/Knob Set at 0%

FIG. 11A illustrates an example virtual dial 1100 that is set at 0% of its dial range of motion, according to some embodiments. As shown, dial 1100 is rotated to 0% (e.g., 0°) of its dial range of motion when set. In some example implementations, a virtual dial is described. In this example implementation, referring also to FIG. 10, knob 1000 is set at 100% of its control range of motion. In various implementations, any suitable type of virtual element may be used (e.g., a virtual slider, etc.). As such, the implementations described herein also apply to other types of virtual elements such as virtual sliders.

As shown, dial 1100 has a position indicator 1102 showing the positioning of dial 1100 relative to one or more static position indicators (e.g., static position indicator 1104). As dial 1100 rotates, position indicator 1102 moves relative to static position indicator 1004. For ease of illustration, only one static position indicator is shown. In various implementations, the specific number of static position indicators may vary, depending on the specific implementation.

In various implementations, dial 1100 has a range of motion, also referred to as a dial range of motion, as indicated above. As shown, the dial range of motion has a minimum dial position (labeled “Min”) and a maximum dial position (labeled “Max”). In various implementations, dial 1100 may be rotated clockwise toward the maximum dial position, and may be rotated counter clockwise toward the minimum dial position. This dial range of motion may encompass a known sound parameter/variable range (e.g., 0 db to 100 db) of a particular sound variable (e.g., volume).

As indicated above, in various implementations, dial 1100 may be initially set or initialized, and associated with knob 1000.

Referring to both FIGS. 10 and 11A, knob 1000 is initially set at 0% of its control range of motion, and dial 1100 is also initially set at 0% of its dial range of motion. When dial 1100 is associated with knob 1000, dial 1100 tracks knob 1000 in order to visually display values of a corresponding sound variable (e.g., volume).

In various implementations, the preciseness at which the dial tracks the control member is referred to as the resolution. For example, a normal resolution may be where knob 1000 rotates from 0% to 50% of its control range of motion and dial 1100 also rotates from 0% to 50% of its control range of motion together. In other words, dial 1100 rotates at the same speed as knob 1000.

In some implementations, the resolution is inversely proportional to the ratio of the dial speed to the knob speed. Stated differently, the resolution is also be inversely proportional to the ratio of the dial range of motion to the knob range of motion, which is 100/100. In this scenario, dial 1100 tracks knob 1000 linearly. This may be referred to as a normal resolution.

In various implementations, processor 102 enables a user to initially set/initialize a given control member such as knob 1000 and also set/initialize one or more dials. Processor 102 also enables the user to associate the control member to the dials. For example, processor 102 may receive an associate indication from the user, which could be provided when the user sets the desired control member and dials and then depresses an associate button. In some implementations, processor 102 may enable the user to set the desired control member and dials and then automatically associate them after a predetermined time period (e.g., 5 second, 10 seconds, etc.).

Dial Set at 25%/Knob Set at 0%

FIG. 11B illustrates an example virtual dial 1100 that is set at 25% of its dial range of motion, according to some embodiments. As shown, dial 1100 is rotated to 25% (e.g., 90°) of its dial range of motion when set. In this example implementation, referring also to FIG. 10, knob 1000 remains set at 0% of its control range of motion.

In various implementations, the initial dial position and the initial control position determine a base value associated with a given sound variable. In some instances, the movement of the control member may cause a nonlinear change in values of one or more sound variables.

In this example implementation, the base value is set at 25% of the dial range of motion. As such, dial 1100 covers the values of the associated sound variable from 25% to 100%. For example, if the associated sound variable is volume and the available values are 0 db up to 100 db, dial 1100 would cover 25 db to 100 db. In other words, 25 db is the minimum value. Such a scenario may be desirable, for example, if the user desires a given sound variable to have a minimum value.

In some implementations, processor 102 may adjust the dial visually to show the limited dial range of motion. For example, in some implementations, processor 102 may remove static position indicators (e.g., remove static position indicators for 0 db up to 25 db).

In this example implementation, dial 1100 covers 75% its dial range of motion (from 25% to 100%), while knob 1000 covers 100% of its control range of motion. Also, dial 1100 is at 25% of its dial range of motion at the same time knob 1000 is at 0% of its control range. Also, dial 1100 and knob 1000 are at 100% of their respective ranges at the same time. As a result, dial 1100 rotates at a slower speed relative to knob 1000.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 0%, knob 1000 may rotate on the + side of the initial knob position. In this example implementation, knob 1000 will not rotate on the − side of the initial knob position, because it is already at its minimum position. The ratio of the dial range of motion to the knob range of motion is 75/100. As such, in this scenario, dial 1100 rotates at a slower speed (75/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 75/100. As such, in this scenario, dial 1100 tracks knob 1000 nonlinearly. This may be referred to as a higher resolution. In other words, the dial associated with the knob has a higher resolution than the knob.

The significance (or benefit) of this behavior and resulting resolution is that the user has a finer degree of control of sound variable, which is more clearly illustrated below in connection with FIG. 11D.

Dial Set at 50%/Knob Set at 0%

FIG. 11C illustrates an example virtual dial 1100 that is set at 50% of its dial range of motion, according to some embodiments. As shown, dial 1100 is rotated to 50% (e.g., 180°) of its dial range of motion when set. In this example implementation, referring also to FIG. 10, knob 1000 remains set at 0% of its control range of motion.

In this example implementation, the base value is set at 50% of the dial range of motion. As such, dial 1100 covers the values of the associated sound variable from 50% to 100%. For example, if the associated sound variable is volume and the available values are 0 db up to 100 db, dial 1100 at 50% would cover 50 db to 100 db. In other words, 50 db is the minimum value.

In this example implementation, dial 1100 covers 50% its dial range of motion (from 50% to 100%), while knob 1000 covers 100% of its control range of motion. Also, dial 1100 is at 50% of its dial range of motion at the same time knob 1000 is at 0% of its control range. Also, dial 1100 and knob 1000 are at 100% of their respective ranges at the same time. As a result, dial 1100 rotates at a slower speed relative to knob 1000.

As indication above, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 0%, knob 1000 may rotate on the + side of the initial knob position. Knob 1000 will not rotate on the − side of the initial knob position, because knob 1000 is already at its minimum value. The ratio of the dial range of motion to the knob range of motion is 50/100. As such, in this scenario, dial 1100 rotates at a slower speed (50/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 50/100. As such, in this scenario, dial 1100 also tracks knob 1000 nonlinearly. This may also be referred to as a higher resolution.

Dial Set at 75%/Knob Set at 0%

FIG. 11D illustrates an example virtual dial 1100 that is set at 75% of its dial range of motion, according to some embodiments. As shown, dial 1100 is rotated to 75% (e.g., 270°) of its dial range of motion when set. In this example implementation, referring also to FIG. 10, knob 1000 remains set at 0% of its control range of motion.

In this example implementation, the base value is set at 75% of the dial range of motion. As such, dial 1100 covers the values of the associated sound variable from 75% to 100%. For example, if the associated sound variable is volume and the available values are 0 db up to 100 db, dial 1100 at 75% would cover 75 db to 100 db. In other words, 75 db is the minimum value.

In this example implementation, dial 1100 covers 25% its dial range of motion (from 75% to 100%), while knob 1000 covers 100% of its control range of motion. Also, dial 1100 is at 75% of its dial range of motion at the same time knob 1000 is at 0% of its control range. Also, dial 1100 and knob 1000 are at 100% of their respective ranges at the same time. As a result, dial 1100 rotates at a slower speed relative to knob 1000.

As indication above, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 0%, knob 1000 may rotate on the + side of the initial knob position. Knob 1000 will not rotate on the − side of the initial knob position, because it is already at its minimum position. The ratio of the dial range of motion to the knob range of motion is 25/100. As such, in this scenario, dial 1100 rotates at a slower speed (25/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 25/100. As such, in this scenario, dial 1100 also tracks knob 1000 nonlinearly. This may also be referred to as a higher resolution. As such, in various implementations, the full control range of motion may control a partial dial range of motion.

As indicated above, the significance (or benefit) of this behavior and resulting resolution is that the user has a finer degree of control of the sound variable. For example, the user needs to rotate knob 1000 four times the amount that dial 1100 rotates from its minimum to maximum positions (e.g., 75 db to 100 db). This gives the user more control when manipulating the values within this range.

In some implementations, processor 102 may automatically adjust the static position indicators of the dial such that the partial range (e.g., 75 db to 100 db) expands visually to span the entire/full range (e.g., 360°) of the dial. In other words, for example, static position indicators describing 75 db to 100 db would be more spread out over 360° of dial 1100 rather than over 90° of dial 1100. Furthermore, instead of the position indicator showing increments of whole numbers (e.g., 75 db, 76 db, 77 db, etc.), the position indicator may show smaller increments such as decimal fractions (e.g., 75 db, 75.5 db, 76 db, 76.5 db, 77 db, 77.5 db, etc.). This, in effect, would increase the resolution of dial 1100 for the user, giving the user more precise control when controlling the associated sound variable.

Dial Set at 100%/Knob Set at 0%

FIG. 11E illustrates an example virtual dial 1100 that is set at 100% of its dial range of motion, according to some embodiments. As shown, dial 1100 is rotated to 100% (e.g., 360°) of its dial range of motion when set. In this example implementation, referring also to FIG. 10, knob 1000 remains set at 0% of its control range of motion.

This particular scenario is unlikely, because when dial 1100 is associated with knob 1000, dial 1100 covers 0% of its dial range of motion. This is because, in this particular scenario, dial 1100 is already at its maximum position. Knob 1000 may rotate on the + side of the initial knob position. Knob 1000 will not rotate on the − side of the initial knob position, because knob 1000 is already at its minimum position.

As seen in these examples in connection with FIGS. 11A through 11E, in some implementations, when initial dial position is set higher than the initial knob position, and initial dial position is at the minimum position of the dial range of motion, the dial will only go up because the knob position is at the minimum position of the control range of motion. The different initial set points of the dial generally result in higher resolutions. As such, in some implementations, the maximum resolution may occur when the difference between the initial dial position and the initial knob position is greatest (e.g., initial dial position approaches 100% and initial knob position approaches 0%). In other words, the resolution may be proportional to the difference between the initial knob position and initial dial position, when the initial knob position is at an extreme (e.g., 0% or 100%).

Scenarios with Knob Set at 50%

FIGS. 12, 13A, 13B, 13C, 13D, and 13E illustrate scenarios where a control member (e.g., a knob) is initially set/initialized at 50% of its control range of motion, and where a dial is initially set/initialized at either 0%, 25%, 50%, 75%, or 100%, respectively, of its dial range of motion.

FIG. 12 illustrates an example top view of a control member 1000 that is set at 50% of its control range of motion, according to some embodiments. As shown, knob 1000 is rotated to 50% (e.g., 180°) of its control range of motion when set. In this particular implementation, the initial control position is set at 50%. Example implementations of how knob 1000 operates when its initial control position is set at 50% are described in more detail below in connection with FIGS. 13A through 13E.

Dial Set at 0%/Knob Set at 50%

FIG. 13A illustrates an example virtual dial 1100 that is set at 0% of its dial range of motion, according to some embodiments. As shown, dial 1100 is rotated to 0% (e.g., 0°) of its dial range of motion when set. In this example implementation, referring also to FIG. 12, knob 1000 remains set at 50% of its control range of motion.

In this example implementation, the base value is set at 0% of the dial range of motion. As such, dial 1100 covers the values of the associated sound variable from 0% to 100%. For instance, continuing with the example where the associated sound variable is volume and the available values are 0 db to 100 db, dial 1100 at 0% would cover 0 db to 100 db. In other words, 0 db is the minimum value, and 100 db is the maximum value.

In this example implementation, dial 1100 covers 100% of its dial range of motion (from 0% to 100%), while knob 1000 covers 50% of its control range of motion on the + side of the initial knob position. While knob 1000 covers 50% of its control range of motion on the − side of the initial knob position, dial 1100 remains at 0% of its dial range of motion. Also, dial 1100 and knob 1000 are at 100% of their respective ranges of motion at the same time. Also dial is at 0% of its dial range of motion at the same time that knob 1000 is at 50% of its control range of motion. As a result, dial 1100 rotates at a faster speed relative to knob 1000.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 50%, knob 1000 may rotate on the + side of the initial knob position (e.g., 50% to 100% of its control range of motion) and may rotate on the − side of the initial knob position (e.g., 0% to 50% of its control range of motion).

On the + side, the ratio of the dial range of motion to the knob range of motion is 100/50. As such, in this scenario, dial 1100 rotates at a faster speed (100/50) relative to the speed of knob 1000.

On the − side, dial 1100 is already at 0% and thus will not rotate when knob 1000 moves in the − direction. In other words, on the − side, knob 1000 would not affect dial 1100.

In this example, the resolution is inversely proportional to the ratio of the dial speed to the knob speed. Stated differently, the resolution is also inversely proportional to the ratio of the dial range of motion to the knob range of motion. On the + side, the ratio is 100/50. As such, in this scenario, dial 1100 tracks knob 1000 nonlinearly on the + side. This may be referred to as a lower resolution.

Dial Set at 25%/Knob Set at 50%

FIG. 13B illustrates an example virtual dial 1100 that is set at 25% of its dial range of motion, according to some embodiments. As shown, dial 1100 is rotated to 25% (e.g., 90°) of its dial range of motion when set. In this example implementation, referring also to FIG. 12, knob 1000 remains set at 50% of its control range of motion.

In this example implementation, the base value is set at 25% of the dial range of motion. As such, dial 1100 covers the values of the associated sound variable from 25% to 100%. For instance, continuing with the example where the associated sound variable is volume and the available values are 0 db to 100 db, dial 1100 at 25% would cover 25 db to 100 db when knob 1000 moves on the + side of the initial knob position. Also, dial 1100 at 25% would cover 0 db to 25 db when knob 1000 moves on the − side of the initial knob position.

In this example implementation, dial 1100 covers 75% of its dial range of motion (from 25% to 100%), while knob 1000 covers 50% of its control range of motion on the + side of the initial knob position. Also, dial 1100 covers 25% of its dial range of motion (from 0% to 25%), while knob 1000 covers 50% of its control range of motion on the − side of the initial knob position. In this example implementation, dial 1100 and knob 1000 are at 0% and 100% of their respective ranges at the same time. Also, dial 1100 is at 25% of its dial range of motion at the same time that knob 1000 is at 50% control range of motion. As a result, dial 1100 rotates at a faster speed relative to knob 1000 when on the + side of the initial knob position, and dial 1100 rotates at a slower speed relative to knob 1000 when on the − side of the initial knob position.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 50%, knob 1000 may rotate on the + side of the initial knob position (e.g., 50% to 100% of its control range of motion) and may rotate on the − side of the initial knob position (e.g., 0% to 50% of its control range of motion).

On the + side, the ratio of the dial range of motion to the knob range of motion is 75/50. As such, in this scenario, dial 1100 rotates at a faster speed (75/50) relative to the speed of knob 1000.

On the − side, the ratio of the dial range of motion to the knob range of motion is 25/50. As such, in this scenario, dial 1100 rotates at a slower speed (25/50) relative to the speed of knob 1000.

In this example, the resolution is inversely proportional to the ratio of the dial speed to the knob speed. Stated differently, the resolution is also inversely proportional to the ratio of the dial range of motion to the knob range of motion. On the + side, the ratio is 75/50. As such, in this scenario, dial 1100 tracks knob 1000 nonlinearly. This may be referred to as a lower resolution. On the − side, the ratio is 25/50. This may be referred to as a higher resolution.

Dial Set at 50%/Knob Set at 50%

FIG. 13C illustrates an example virtual dial 1100 that is set at 50% of its dial range of motion, according to some embodiments. As shown, dial 1100 is rotated to 50% (e.g., 180°) of its dial range of motion when set. In this example implementation, referring also to FIG. 12, knob 1000 remains set at 50% of its control range of motion.

In this example implementation, the base value is set at 50% of the dial range of motion. As such, dial 1100 covers the values of the associated sound variable from 50% to 100%. For instance, continuing with the example where the associated sound variable is volume and the available values are 0 db to 100 db, dial 1100 at 50% would cover 50 db to 100 db. In other words, 50 db is the minimum value.

In this example implementation, dial 1100 covers 50% of its dial range of motion (from 50% to 100%), while knob 1000 covers 50% of its control range of motion on the + side of the initial knob position. Also, dial 1100 covers 50% of its dial range of motion (from 0% to 50%), while knob 1000 covers 50% of its control range of motion on the + side of the initial knob position. Also, dial 1100 and knob 1000 are at 0% of their respective ranges of motion at the same time, at 50% of their respective ranges of motion at the same time, and at 100% of their respective ranges of motion at the same time. As a result, dial 1100 rotates at the same speed relative to knob 1000.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 50%, knob 1000 may rotate on the + side of the initial knob position (e.g., 50% to 100% of its control range of motion) and may rotate on the − side of the initial knob position (e.g., 0% to 50% of its control range of motion).

On the + side, the ratio of the dial range of motion to the knob range of motion is 50/50. As such, in this scenario, dial 1100 rotates at the same speed (50/50) relative to the speed of knob 1000.

On the − side, the ratio of the dial range of motion to the knob range of motion is 50/50. As such, in this scenario, dial 1100 rotates at the same speed (50/50) relative to the speed of knob 1000.

In this example, the resolution is inversely proportional to the ratio of the dial speed to the knob speed. Stated differently, the resolution is also inversely proportional to the ratio of the dial range of motion to the knob range of motion. On the + side, the ratio is 50/50. As such, in this scenario, dial 1100 tracks knob 1000 linearly. This may be referred to as a normal resolution. On the − side, the ratio is 50/50. This may also be referred to as a normal resolution.

Dial Set at 75%/Knob Set at 50%

FIG. 13D illustrates an example virtual dial 1100 that is set at 75% of its dial range of motion, according to some embodiments. As shown, dial 1100 is rotated to 75% (e.g., 270°) of its dial range of motion when set. In this example implementation, referring also to FIG. 12, knob 1000 remains set at 50% of its control range of motion.

In this example implementation, the base value is set at 75% of the dial range of motion. As such, dial 1100 covers the values of the associated sound variable from 75% to 100%. For instance, continuing with the example where the associated sound variable is volume and the available values are 0 db to 100 db, dial 1100 at 75% would cover 75 db to 100 db when knob 1000 moves on the + side of the initial knob position. Also, dial 1100 at 75% would cover 0 db to 75 db when knob 1000 moves on the − side of the initial knob position.

In this example implementation, dial 1100 covers 25% of its dial range of motion (from 75% to 100%), while knob 1000 covers 50% of its control range of motion on the + side of the initial knob position. Also, dial 1100 covers 75% of its dial range of motion (from 0% to 75%), while knob 1000 covers 50% of its control range of motion on the − side of the initial knob position. In this example implementation, dial 1100 and knob 1000 are at 0% and 100% of their respective ranges at the same time. Also, dial 1100 is at 75% of its dial range of motion at the same time that knob 1000 is at 50% control range of motion. As a result, dial 1100 rotates at a slower speed relative to knob 1000 when on the + side of the initial knob position, and dial 1100 rotates at a faster speed relative to knob 1000 when on the − side of the initial knob position.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 50%, knob 1000 may rotate on the + side of the initial knob position (e.g., 50% to 100% of its control range of motion) and may rotate on the − side of the initial knob position (e.g., 0% to 50% of its control range of motion).

On the + side, the ratio of the dial range of motion to the knob range of motion is 25/50. As such, in this scenario, dial 1100 rotates at a slower speed (25/50) relative to the speed of knob 1000.

On the − side, the ratio of the dial range of motion to the knob range of motion is 75/50. As such, in this scenario, dial 1100 rotates at a faster speed (75/50) relative to the speed of knob 1000.

In this example, the resolution is inversely proportional to the ratio of the dial speed to the knob speed. Stated differently, the resolution is also inversely proportional to the ratio of the dial range of motion to the knob range of motion. On the + side, the ratio is 25/50. As such, in this scenario, dial 1100 tracks knob 1000 nonlinearly. This may be referred to as a higher resolution. On the − side, the ratio is 75/50. This may be referred to as a lower resolution.

Dial Set at 100%/Knob Set at 50%

FIG. 13E illustrates an example virtual dial 1100 that is set at 100% of its dial range of motion, according to some embodiments. As shown, dial 1100 is rotated to 100% (e.g., 360°) of its dial range of motion when set. In this example implementation, referring also to FIG. 12, knob 1000 remains set at 50% of its control range of motion.

In this example implementation, the base value is set at 100% of the dial range of motion. As such, dial 1100 covers the values of the associated sound variable from 0% to 100%. For instance, continuing with the example where the associated sound variable is volume and the available values are 0 db to 100 db, dial 1100 at 100% would cover 0 db to 100 db. In other words, 0 db is the minimum value, and 100 db is the maximum value.

In this example implementation, dial 1100 covers 100% of its dial range of motion (from 0% to 100%), while knob 1000 covers 50% of its control range of motion on the − side of the initial knob position. While knob 1000 covers 50% of its control range of motion on the + side of the initial knob position, dial 1100 remains at 100% of its dial range of motion. Also, dial 1100 and knob 1000 are at 0% of their respective ranges of motion at the same time. Also dial is at 100% of its dial range of motion at the same time that knob 1000 is at 50% of its control range of motion. As a result, dial 1100 rotates at a faster speed relative to knob 1000.

In this example implementation, when dial 1100 is associated with knob 1000, dial 1100 covers 100% of its dial range of motion, and knob 1000 covers 100% of its control range of motion. As shown, dial 1100 and knob 1000 are at 100% of their respective ranges of motion at the same time. Also, dial 1100 is at 0% of its dial range of motion at the same time that knob 1000 is at 0% of its range of motion. As a result, dial 1100 rotates at a faster speed relative to knob 1000.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 50%, knob 1000 may rotate on the + side of the initial knob position (e.g., 50% to 100% of its control range of motion) and may rotate on the − side of the initial knob position (e.g., 0% to 50% of its control range of motion).

On the + side, dial 1100 is already at 100% and thus will not rotate when knob 1000 moves in the + direction. In other words, on the + side, knob 1000 would not affect dial 1100.

On the − side, the ratio of the dial range of motion to the knob range of motion is 100/50. As such, on the − side, dial 1100 rotates at a faster speed (100/50) relative to the speed of knob 1000.

In this example, the resolution is inversely proportional to the ratio of the dial speed to the knob speed. Stated differently, the resolution is also inversely proportional to the ratio of the dial range of motion to the knob range of motion. On the − side, the ratio is 100/50. As such, in this scenario, dial 1100 tracks knob 1000 nonlinearly on the − side. This may be referred to as a lower resolution.

Scenarios with Knob Set at 100%

FIGS. 14, 15A, 15B, 15C, 15D, and 15E illustrate scenarios where a control member (e.g., a knob) is initially set/initialized at 100% of its control range of motion, and where a dial is initially set/initialized at either 0%, 25%, 50%, 75%, or 100%, respectively, of its dial range of motion.

FIG. 14 illustrates an example top view of a control member 1000 that is set at 100% of its control range of motion, according to some embodiments. As shown, control knob 1000 is rotated to 100% (e.g., 360°) of its control range of motion when set. In this particular implementation, the initial control position is set at 100%. Examples implementations of how knob 1000 operates when its initial control position is set at 100% is described in more detail below in connection with FIGS. 15A through 15E.

Dial Set at 0%/Knob Set at 100%

FIG. 15A illustrates an example virtual dial 1100 that is set at 0% of its dial range of motion, according to some embodiments. As shown, dial 1100 is rotated to 0% (e.g., 0°) of its dial range of motion when set. In this example implementation, referring also to FIG. 14, knob 1000 is set at 100% of its control range of motion.

This particular scenario is unlikely, because when dial 1100 is associated with knob 1000, dial 1100 covers 0% of its dial range of motion. This is because, in this particular scenario, dial 1100 is already at its minimum position. Knob 1000 may rotate on the − side of the initial knob position. Knob 1000 will not rotate on the + side of the initial knob position, because knob 1000 is already at its maximum position.

Dial Set at 25%/Knob Set at 100%

FIG. 15B illustrates an example virtual dial 1100 that is set at 25% of its dial range of motion, according to some embodiments. As shown, dial 1100 is rotated to 25% (e.g., 90°) of its dial range of motion when set. In this example implementation, referring also to FIG. 14, knob 1000 remains set at 100% of its control range of motion.

In this example implementation, the base value is set at 25% of the dial range of motion. As such, dial 1100 covers the values of the associated sound variable from 0% to 25%. For instance, continuing with the example where the associated sound variable is volume and the available values are 0 db up to 100 db, dial 1100 at 25% would cover 0 db to 25 db. In other words, 25 db is the maximum value. Such a scenario may be desirable, for example, if the user desires such a maximum value.

In this example implementation, dial 1100 covers 25% its dial range of motion (from 0% to 25%), while knob 1000 covers 100% of its control range of motion. Also, dial 1100 and knob 1000 are at 0% of their respective ranges at the same time. Also, dial 1100 is at 50% of its dial range of motion at the same time knob 1000 is at 100% of its control range. As a result, dial 1100 rotates at a slower speed relative to knob 1000.

As indication above, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 100%, knob 1000 may rotate on the − side of the initial knob position. Knob 1000 will not rotate on the + side of the initial knob position, because knob 1000 is already at its maximum position. The ratio of the dial range of motion to the knob range of motion is 25/100. As such, in this scenario, dial 1100 rotates at a slower speed (25/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 25/100. As such, in this scenario, dial 1100 also tracks knob 1000 nonlinearly. This may also be referred to as a higher resolution.

Dial Set at 50%/Knob Set at 100%

FIG. 15C illustrates an example virtual dial 1100 that is set at 50% of its dial range of motion, according to some embodiments. As shown, dial 1100 is rotated to 50% (e.g., 180°) of its dial range of motion when set. In this example implementation, referring also to FIG. 14, knob 1000 remains set at 100% of its control range of motion.

In this example implementation, the base value is set at 50% of the dial range of motion. As such, dial 1100 covers the values of the associated sound variable from 0% to 50%. For instance, continuing with the example where the associated sound variable is volume and the available values are 0 db up to 100 db, dial 1100 at 50% would cover 0 db to 50 db. In other words, 50 db is the maximum value.

In this example implementation, dial 1100 covers 50% its dial range of motion (from 0% to 50%), while knob 1000 covers 100% of its control range of motion. Also, dial 1100 and knob 1000 are at 0% of their respective ranges at the same time. Also, dial 1100 is at 50% of its dial range of motion at the same time knob 1000 is at 100% of its control range. As a result, dial 1100 rotates at a slower speed relative to knob 1000.

As indication above, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 100%, knob 1000 may rotate on the − side of the initial knob position. Knob 1000 will not rotate on the + side of the initial knob position, because knob 1000 is already at its maximum position. The ratio of the dial range of motion to the knob range of motion is 50/100. As such, in this scenario, dial 1100 rotates at a slower speed (50/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 50/100. As such, in this scenario, dial 1100 also tracks knob 1000 nonlinearly. This may also be referred to as a higher resolution.

Dial Set at 75%/Knob Set at 100%

FIG. 15D illustrates an example virtual dial 1100 that is set at 75% of its dial range of motion, according to some embodiments. As shown, dial 1100 is rotated to 75% (e.g., 270°) of its dial range of motion when set. In this example implementation, referring also to FIG. 14, knob 1000 remains set at 100% of its control range of motion.

In this example implementation, the base value is set at 75% of the dial range of motion. As such, dial 1100 covers the values of the associated sound variable from 0% to 75%. For instance, continuing with the example where the associated sound variable is volume and the available values are 0 db up to 100 db, dial 1100 at 75% would cover 0 db to 75 db. In other words, 75 db is the maximum value.

In this example implementation, dial 1100 covers 75% its dial range of motion (from 0% to 75%), while knob 1000 covers 100% of its control range of motion. Also, dial 1100 and knob 1000 are at 0% of their respective ranges at the same time. Also, dial 1100 is at 75% of its dial range of motion at the same time knob 1000 is at 100% of its control range. As a result, dial 1100 rotates at a slower speed relative to knob 1000.

As indication above, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position). In this example implementation, with the initial control position at 100%, knob 1000 may rotate on the − side of the initial knob position. Knob 1000 will not rotate on the + side of the initial knob position, because knob 1000 is already at its maximum position. The ratio of the dial range of motion to the knob range of motion is 75/100. As such, in this scenario, dial 1100 rotates at a slower speed (75/100) relative to the speed of knob 1000.

In this example, the resolution is inversely proportional to the ratio of the dial speed to the knob speed. Stated differently, the resolution is also inversely proportional to the ratio of the dial range of motion to the knob range of motion, which is 75/100. As such, in this scenario, dial 1100 also tracks knob 1000 nonlinearly. This may also be referred to as a higher resolution.

Dial Set at 100%/Knob Set at 100%

FIG. 15E illustrates an example virtual dial 1100 that is set at 100% of its dial range of motion, according to some embodiments. As shown, dial 1100 is rotated to 100% (e.g., 360°) of its dial range of motion when set. In this example implementation, referring also to FIG. 14, knob 1000 remains set at 100% of its control range of motion.

In this example implementation, the base value is set at 100% of the dial range of motion. As such, dial 1100 covers the values of the associated sound variable from 0% to 100%. For instance, continuing with the example where the associated sound variable is volume and the available values are 0 db to 100 db, dial 1100 at 100% would cover 0 db to 100 db. In other words, 0 db is the minimum value, and 100 db is the maximum value.

In this example implementation, dial 1100 covers 100% its dial range of motion (from 0% to 100%), while knob 1000 covers 100% of its control range of motion. Also, dial 1100 and knob 1000 are at 0% and 100% of their respective ranges at the same time. As a result, dial 1100 rotates at a slower speed relative to knob 1000.

In various implementations, the dial speed relative to the knob speed is inversely proportional to the ratio of the dial range of motion to the knob range of motion when the knob moves within a range on one side of the initial knob position (e.g., either on the + side of the initial knob position or on the − side of the initial knob position).

In this example implementation, with the initial control position at 100%, knob 1000 may rotate on the − side of the initial knob position. Knob 1000 would not rotate on the + side of the initial knob position because knob 1000 is already at its maximum position.

On the + side, the ratio of the dial range of motion to the knob range of motion is 50/50. As such, in this scenario, dial 1100 rotates at the same speed (50/50) relative to the speed of knob 1000.

On the − side, the ratio of the dial range of motion to the knob range of motion is 100/100. As such, in this scenario, dial 1100 rotates at the same speed (100/100) relative to the speed of knob 1000.

In this example, the resolution is inversely proportional to the ratio of the dial speed to the knob speed. Stated differently, the resolution is also inversely proportional to the ratio of the dial range of motion to the knob range of motion. The + side would not apply for the reason stated above. On the − side, the ratio is 100/100. This may also be referred to as a normal resolution.

In various implementations, one control member may simultaneously control multiple dials. For example, knob 1000 may simultaneously control different dials associated sound variables such as volume, reverb, distortion, etc. In other words, each control member may function as a master control of multiple dials, and thus of multiple sound parameters/variables.

As described above in various example implementations, each dial may rotate at a speed that is the same as or different from the associated control member. As such, when a given control member functions as a master control, the different associated dials may rotate at different rates relative to the speed of the control member. Also, the values of the different associated sound variables will also change at different rates relative to the speed of the control member. This may be desirable to a musician or disk jockey who may want different sound variables to change at different rates with the control of a single master control member.

Embodiments described herein provide various benefits. For example, embodiments enable a user to intuitively and precisely control one or more music variables using a physical controller such as a knob or slider. Embodiments also enable a user to conveniently see how such music variables change using one or more software indicators such as virtual dials. Embodiments also enable a user to increase or decrease the resolution of one or more dials based on initial settings of a given physical controller and the one or more dials.

Although the description has been described with respect to particular embodiments thereof, these particular embodiments are merely illustrative, and not restrictive. Any suitable programming language can be used to implement the routines of particular embodiments including C, C++, Java, assembly language, etc. Different programming techniques can be employed such as procedural or object oriented. The routines can execute on a single processing device or multiple processors. Although the steps, operations, or computations may be presented in a specific order, this order may be changed in different particular embodiments. In some particular embodiments, multiple steps shown as sequential in this specification can be performed at the same time.

Particular embodiments may be implemented in a computer-readable storage medium for use by or in connection with the instruction execution system, apparatus, system, or device. Particular embodiments can be implemented in the form of control logic in software or hardware or a combination of both. The control logic, when executed by one or more processors, may be operable to perform that which is described in particular embodiments.

Particular embodiments may be implemented by using a programmed general purpose digital computer, by using application specific integrated circuits, programmable logic devices, field programmable gate arrays, optical, chemical, biological, quantum or nanoengineered systems, components and mechanisms may be used. In general, the functions of particular embodiments can be achieved by any means as is known in the art. Distributed, networked systems, components, and/or circuits can be used. Communication, or transfer, of data may be wired, wireless, or by any other means.

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

A “processor” includes any suitable hardware and/or software system, mechanism or component that processes data, signals or other information. A processor can include a system with a general-purpose central processing unit, multiple processing units, dedicated circuitry for achieving functionality, or other systems. Processing need not be limited to a geographic location, or have temporal limitations. For example, a processor can perform its functions in “real time,” “offline,” in a “batch mode,” etc. Portions of processing can be performed at different times and at different locations, by different (or the same) processing systems. A computer may be any processor in communication with a memory. The memory may be any suitable processor-readable storage medium, such as random-access memory (RAM), read-only memory (ROM), magnetic or optical disk, or other tangible media suitable for storing instructions for execution by the processor.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular embodiments have been described herein, latitudes of modification, various changes, and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit.

We claim:

1. A method comprising:
determining an initial control position of at least one control member of a hardware control device;
determining an initial dial position of at least one dial; and
modifying a value of at least one sound variable based on the initial control position, the initial dial position, and movement of the at least one control member.

2. The method of claim 1, wherein the initial dial position and the initial control position determine a base value associated with at least one sound variable.

3. The method of claim 1, wherein the movement of the at least one control member causes the value of the at least one sound variable to change based on the initial dial position and the initial control position.

4. The method of claim 1, enabling the at least one dial to be changed based on the movement of the at least one control member.

5. The method of claim 1, enabling multiple dials to be changed based on the movement of a single control member.

6. The method of claim 1, wherein the at least one dial has a dial range of motion, and wherein the dial range of motion has a minimum dial position and a maximum dial position.

7. The method of claim 1, wherein the at least one control member has a control range of motion, and wherein the control range of motion has a minimum control position and a maximum control position.

8. A computer-readable storage medium carrying one or more sequences of instructions thereon, the instructions when executed by a processor cause the processor to perform operations including:
determining an initial control position of at least one control member of a hardware control device;
determining an initial dial position of at least one dial; and
modifying a value of at least one sound variable based on the initial control position, the initial dial position, and movement of the at least one control member.

9. The computer-readable storage medium of claim 8, wherein the initial dial position and the initial control position determine a base value associated with at least one sound variable.

10. The computer-readable storage medium of claim 8, wherein the movement of the at least one control member causes the value of the at least one sound variable to change based on the initial dial position and the initial control position.

11. The computer-readable storage medium of claim 8, wherein the instructions further cause the processor to perform operations including enabling the at least one dial to be changed based on the movement of the at least one control member.

12. The computer-readable storage medium of claim 8, wherein the instructions further cause the processor to perform operations including enabling multiple dials to be changed based on the movement of a single control member.

13. The computer-readable storage medium of claim 8, wherein the at least one dial has a dial range of motion, and wherein the dial range of motion has a minimum dial position and a maximum dial position.

14. The computer-readable storage medium of claim 8, wherein the at least one control member has a control range of motion, and wherein the control range of motion has a minimum control position and a maximum control position.

15. A system comprising:
one or more processors; and
logic encoded in one or more tangible media for execution by the one or more processors, and when executed operable to perform operations comprising:
determining an initial control position of at least one control member of a hardware control device;
determining an initial dial position of at least one dial; and
modifying a value of at least one sound variable based on the initial control position, the initial dial position, and movement of the at least one control member.

16. The system of claim 15, wherein the initial dial position and the initial control position determine a base value associated with at least one sound variable.

17. The system of claim 15, wherein the movement of the at least one control member causes the value of the at least one sound variable to change based on the initial dial position and the initial control position.

18. The system of claim 15, wherein the logic when executed is further operable to perform operations including enabling the at least one dial to be changed based on the movement of the at least one control member.

19. The system of claim 15, wherein the logic when executed is further operable to perform operations including enabling multiple dials to be changed based on the movement of a single control member.

20. The system of claim 15, wherein the at least one dial has a dial range of motion, and wherein the dial range of motion has a minimum dial position and a maximum dial position.
